(19) United States
(12) Patent Application Publication
(10) Pub. No.: US 2026/0218412 A1
(43) Pub. Date: Jul. 30, 2026

(54) GALLIUM NITRIDE CRYSTAL SUBSTRATE AND METHOD FOR MANUFACTURING GALLIUM NITRIDE CRYSTAL SUBSTRATE

(71) Applicant: SUMITOMO CHEMICAL COMPANY, LIMITED, Tokyo (JP)

(72) Inventors: Toshio KITAMURA, Hitachi-shi (JP); Takashi SATO, Hitachi-shi (JP); Tetsuji FUJIMOTO, Hitachi-shi (JP)

(73) Assignee: SUMITOMO CHEMICAL COMPANY, LIMITED, Tokyo (JP)

(21) Appl. No.: 19/456,324

(22) Filed: Jan. 22, 2026

(30) Foreign Application Priority Data
Jan. 29, 2025 (JP) 2025-013075

(51) Int. Cl. C30B 25/14; C30B 29/40; C30B 31/16

(52) U.S. Cl. CPC C30B 25/14; C30B 29/406; C30B 31/16

(57) ABSTRACT

There is provided a gallium nitride crystal substrate, the gallium nitride crystal substrate having a main surface whose closest low-index crystal plane is (0001), wherein an impurity element most abundant in the gallium nitride crystal substrate is carbon, and a resistivity of the gallium nitride crystal substrate at a temperature of 20° C. is 1×10¹²Ω cm or more.

### BACKGROUND

### Technical Field

The present disclosure relates to a gallium nitride crystal substrate and a method for manufacturing a gallium nitride crystal substrate.

### Description of Related Art

In recent years, for example, a semi-insulating gallium nitride crystal substrate with high resistance is in demand for applications such as high frequency devices and power devices. In order to obtain a gallium nitride crystal substrate with high resistance, p-type impurities (deep acceptors) are sometimes added, that form deep levels in gallium nitride crystals to compensate for n-type impurities. In this case, examples of dopant elements that can be added to the gallium nitride crystal substrate include iron, manganese, and carbon (for example, see Patent Document 1, which discloses carbon doping).

Patent Document 1: JP 2009-117864 A

### SUMMARY OF THE INVENTION

An object of the present disclosure is to reliably obtain a high-resistivity gallium nitride crystal substrate.

According to one aspect of the present disclosure, there is provided a gallium nitride crystal substrate,
the gallium nitride crystal substrate having a main surface whose closest low-index crystal plane is (0001),
wherein an impurity element most abundant in the gallium nitride crystal substrate is carbon, and
a resistivity of the gallium nitride crystal substrate at a temperature of 20° C. is 1×10¹² Ωcm or more.

### Advantageous Effects of Invention

According to the present disclosure, a high-resistivity gallium nitride crystal substrate can be reliably obtained.

### BRIEF DESCRIPTION OF THE DRAWINGS

FIG. 1 is a flowchart showing a method for manufacturing a gallium nitride crystal substrate according to one embodiment of the present disclosure.

FIG. 2 is a schematic view showing a hydride vapor phase growth apparatus according to one embodiment of the present disclosure.

FIG. 3A is a schematic cross-sectional view showing a part of a method for manufacturing a gallium nitride crystal substrate according to one embodiment of the present disclosure.

FIG. 3B is schematic cross-sectional view showing a part of a method for manufacturing a gallium nitride crystal substrate according to one embodiment of the present disclosure.

FIG. 3C is a schematic cross-sectional view showing a part of a method for manufacturing a gallium nitride crystal substrate according to one embodiment of the present disclosure.

FIG. 4 is a schematic cross-sectional view showing a part of a method for manufacturing a gallium nitride crystal substrate according to one embodiment of the present disclosure.

FIG. 5A is a schematic plan view showing a gallium nitride crystal substrate according to one embodiment of the present disclosure.

FIG. 5B is a schematic cross-sectional view showing a gallium nitride crystal substrate according to one embodiment of the present disclosure.

FIG. 6 is a graph showing resistivity ρ of the gallium nitride crystal substrate of an example relative to a carbon concentration [C] in the gallium nitride crystal substrate of an example.

FIG. 7 is a graph showing an Arrhenius plot of resistivity of the gallium nitride crystal substrate of the example.

FIG. 8 is a graph showing a hydrogen concentration [H] in the gallium nitride crystal substrate of an example relative to the carbon concentration [C] in the gallium nitride crystal substrate of the example.

FIG. 9 is a graph showing the ratio [H]/[C], relative to the carbon concentration [C] in the gallium nitride crystal substrate of the example

FIG. 10 is a graph showing the full width at half maximum of (0002) diffraction and the full width at half maximum of (10-12) diffraction, measured by an X-ray rocking curve measurement for the gallium nitride crystal substrate of the example, relative to the carbon concentration [C] in the gallium nitride crystal substrate of the example.

FIG. 11 is a graph showing the radius of curvature of the (0001) of the gallium nitride crystal substrate of the example, relative to the carbon concentration [C] in the gallium nitride crystal substrate of the example.

FIG. 12 is a graph showing an average etch pit density in the main surface of the gallium nitride crystal substrate of the example, relative to the carbon concentration [C] in the gallium nitride crystal substrate of the example.

FIG. 13 is a schematic view showing the configuration of a hydride vapor phase growth apparatus according to a comparative example.

### DETAILED DESCRIPTION OF THE INVENTION

### Findings Obtained by the Inventors

First, the findings obtained by the inventors will be described.

As a method for adding carbon (C) to a crystal layer composed of gallium nitride (GaN) crystal, for example, the following method can be considered: a hydrocarbon gas is supplied together with a source gas by a hydride vapor phase epitaxy (HVPE) method to add C into the crystal layer.

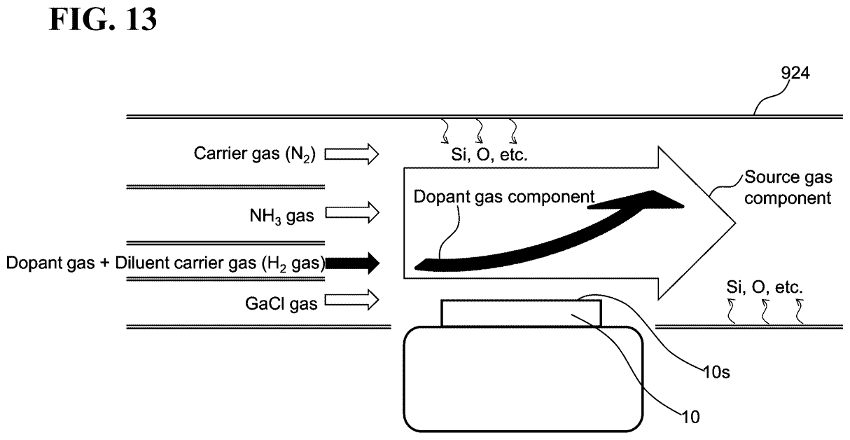

Here, a conventional HVPE apparatus will be described as a comparative example, with reference to FIG. 13.

As shown in FIG. 13, the HVPE apparatus of the comparative example is configured as, for example, a horizontal flow type. In the horizontal flow type HVPE apparatus such as the comparative example, for example, a seed substrate 10 is placed horizontally in a flow channel 924 made of quartz, so that the seed substrate 10 is rotated. Then, a source gas containing gallium chloride (GaCl) gas and ammonia (NH₃) gas, a carrier gas, and a hydrocarbon gas as a dopant gas are supplied along (horizontally) the main surface 10s of the heated seed substrate 10, thereby growing the crystal layer composed of GaN crystal containing C on the seed substrate 10.

When the inventors investigated C doping using the above-described HVPE method, they found that the following new problems (i) and (ii) arise in the manufacturing method using the conventional HVPE apparatus.

### (i) Contamination with Impurities From a Quartz Component

As shown in FIG. 13, in the HVPE apparatus of the comparative example, the quartz constituting the flow channel 924 was exposed inward of the flow channel 924. This caused silicon (Si) and oxygen (O) originating from the quartz to be mixed into the crystal layer composed of GaN crystal.

In this case, due to the above-described contamination with Si and O, the total concentration of the n-type impurities in the GaN crystal becomes high. Therefore, even when C is doped into the GaN crystal by supplying a hydrocarbon gas, the C as a p-type impurity (C substituting the N site) cannot sufficiently compensate for the n-type impurity. As a result, it has become difficult to increase the resistivity of the GaN crystal.

Further, in addition to Si and O, the quartz that constitutes the flow channel 924 contains, boron (B), iron (Fe), alkali metals, alkaline earth metals, etc., at concentrations of approximately less than 0.1 ppm. Therefore, these impurities are also mixed into the crystal layer composed of GaN crystal. This involves a possibility of lowering the crystallinity of the crystal layer.

### (ii) Deviation of a Hydrocarbon Gas Component From the Seed Substrate, Insufficient Decomposition of the Hydrocarbon Gas

As shown in FIG. 13, the source gas, dopant gas, etc., are introduced to the seed substrate 10 from a gas line (gas supply pipe) independently placed upstream in the flow channel 924.

Among the gases flowing through the flow channel 924, the gas with a highest flow rate is a carrier gas. As the carrier gas, nitrogen (N₂) gas or a mixed gas of N₂ gas and hydrogen (H₂) gas is used. Even when the mixed gas of N₂ gas and H₂ gas is used, the ratio of N₂ gas to H₂ gas is very large. The source gases with the next highest flow rates are NH₃ gas and GaCl gas, in that order. For example, NH₃ gas and GaCl gas account for approximately 1/7 and 1/15 of the total flow rate in the flow channel 924, respectively. Hereinafter, the component including the source gas and carrier gas supplied into flow channel 924 will also be referred to as a “source gas component.”

On the other hand, the dopant gas flows in only a small amount relative to the total flow rate in the flow channel 924. The dopant gas is usually diluted with a diluent gas into a predetermined dopant gas concentration before being filled in a gas cylinder. The dopant gas is supplied to the seed substrate 10 from a dopant gas line together with the diluent gas. Hereinafter, the component including the dopant gas and the diluent gas supplied into the flow channel 924 will also be referred to as a “dopant gas component.”

Here, when hydrocarbon molecules as the dopant gas are thermally decomposed, they become C and H₂ gas. Specifically, methane, ethylene, and propane are thermally decomposed according to the following reaction formula:
CH₄→C+2H₂
C₂H₄→2C+2H₂
C₃H₈→3C+4H₂

Conventionally, H₂ gas has generally been used as a diluent gas for diluting a dopant gas, because it is an element that constitutes the dopant gas and can easily be made highly pure.

However, as described above, among the gases flowing through the flow channel 924, the source gas component contained a large amount of N₂ gas as a carrier gas. For this reason, the specific gravity of the dopant gas component containing H₂ gas as a diluent gas is smaller than the specific gravity of the source gas component containing a large amount of N₂ gas as a carrier gas. The “specific gravity” of each gas component here means its specific gravity relative to air under a standard condition.

Conventionally, as described above, since the difference in specific gravity of the dopant gas component and the source gas component was generated, at least a part of the flow of the dopant gas component was bent upward and deviated from the seed substrate 10 in the flow channel 924, as shown in FIG. 13. That is, the dopant gas was less likely to reach the seed substrate 10 sufficiently. As a result, C was less likely to be incorporated into at least a part of the crystal layer growing on the seed substrate 10.

Further, due to the deviation of at least a part of the flow of the dopant gas component from the seed substrate 10, there has been a variation in the amount of C incorporated into the crystal layer in the plane. There has also been a variation in the amount of C incorporated into the crystal layer, as the crystal layer grows in the thickness direction. This caused the C concentration in the crystal layer to be not only non-uniform in the plane but also non-uniform in the thickness direction. As a result, high resistivity measured over an entire thickness was not achieved for the gallium nitride crystal substrate obtained from the crystal layer.

Further, when the H₂ gas was used as a diluent gas for diluting the dopant gas, in the reaction formula of the dopant gas described above, the generation of the H₂ gas was suppressed by the H₂ gas used as a diluent gas, that is, the thermal decomposition itself of the hydrocarbon gas was less likely to occur. Even under such a condition where the thermal decomposition of the hydrocarbon gas is less likely to occur, the total amount of the H₂ gas was increased downstream of the flow channel 924 due to the generation of the small amount of the H₂ gas from the dopant gas, and therefore the thermal decomposition is further less likely to occur downstream. As a result, for this reason also, C was less likely to be incorporated into at least a part of the crystal layer growing on the seed substrate 10.

Further, when suppressing the thermal decomposition of the hydrocarbon gas used as a dopant gas, the dopant gas is more likely to reach the seed substrate 10 in a state where it was not completely thermally decomposed. Therefore, H was incorporated into the crystal layer composed of GaN crystal in a state where H was bonded to C, that is, H was more likely to mix in together with C. As will be described later, there is a possibility that H incorporated into the GaN crystal deactivates C. As a result, it has become difficult to increase the resistivity of the GaN crystal relative to the amount of C doping.

The above phenomenon is unique to C doping, which uses carbon hydride as a dopant gas, and is not observed in the doping with other elements (such as silicon (Si), germanium (Ge), iron (Fe), etc.), which often uses chlorides as a dopant gas in the HVPE method.

The above new problems (i) and (ii) have been explained using a horizontal flow type HVPE apparatus as an example, but they can also occur in a vertical flow type HVPE apparatus.

Therefore, the inventors have conducted extensive research into the above-described new problems (i) and (ii) and have found a novel manufacturing method, which will be described later. As a result, they succeeded in efficiently doping C into a crystal layer composed of GaN crystal while suppressing the contamination with impurity elements other than C.

The present disclosure is based on the above findings made by the inventors.

### DETAILS OF THE EMBODIMENT OF THE PRESENT DISCLOSURE

Next, an embodiment of the present disclosure will be described below with reference to the drawings. The present disclosure is not limited to these examples, but is defined by the scope of the claims, and is intended to include all modifications in the meaning and scope equivalent to the claims.

### One Embodiment of the Present Disclosure

Hereinafter, one embodiment of the present disclosure will be described with reference to the drawings.

### (1) Method for Manufacturing a Gallium Nitride Crystal Substrate

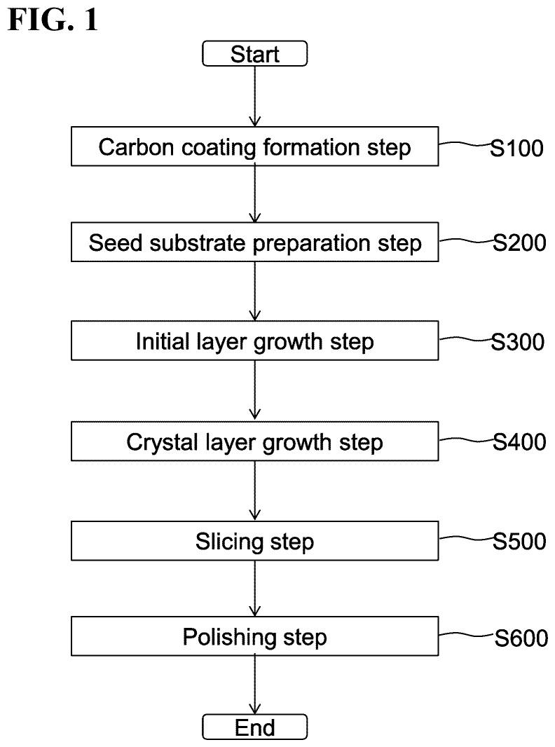

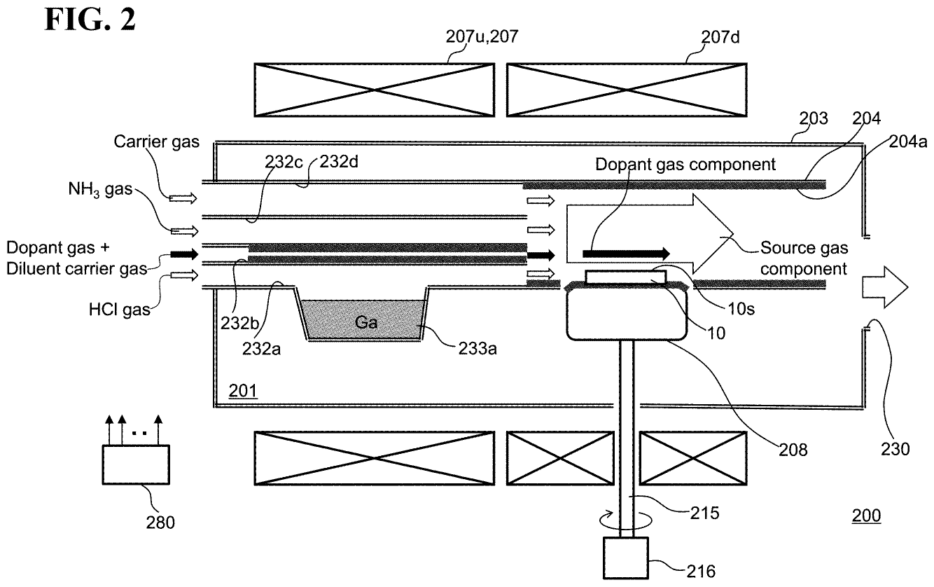

The method for manufacturing a gallium nitride crystal substrate according to this embodiment will be described with reference to FIGS. 1 to 4. In FIGS. 2 to 4, hatching is omitted for areas other than the crystal layer 30.

Hereinafter, in the crystal of a group III nitride semiconductor having a wurtzite structure, <0001> axis (for example, [0001] axis) will be referred to as “c-axis” and (0001) will be referred to as “c-plane”. The (0001) is sometimes called “+c plane (group III element polar plane),” and (000-1) is sometimes called “-c plane (nitrogen (N) polar plane).” Further, <1-100> axis (for example, [1-100] axis) is referred to as “m-axis,” and {1-100} is referred to as “m-plane”. The m-axis may be written as <10-10> axis. <11-20> axis (for example, [11-20] axis) is referred to as “a-axis,” and {11-20} is referred to as “a-plane.”

The method for manufacturing a gallium nitride crystal substrate of this embodiment includes the following steps (A) to (C).
(A) Forming a carbon coating 204a in a flow channel 204 prior to a crystal layer growth step S400;
(B) Adjusting a specific gravity balance of a gas component in the crystal layer growth step S400;
(C) Maintaining the c-plane growth of the crystal layer 30 in the crystal layer growth step S400.

At least (A) efficiently improves the resistivity of the gallium nitride crystal substrate 50 by a low C concentration. (A) to (C) efficiently and reliably improve the resistivity of the gallium nitride crystal substrate 50.

Specifically, as shown in FIG. 1, the method for manufacturing a gallium nitride crystal substrate according to this embodiment includes, for example, a carbon coating formation step S100, a seed substrate preparation step S200, an initial layer growth step S300, a crystal layer growth step S400, a slicing step S500, and a polishing step S600.

### Hydride Vapor Phase Epitaxy (HVPE) Apparatus

First, a HVPE apparatus 200 used in this embodiment will be described, with reference to FIG. 2.

As shown in FIG. 2, the HVPE apparatus 200 of this embodiment is configured as, for example, a horizontal flow type. Specifically, the HVPE apparatus 200 of this embodiment includes, for example, an airtight container 203, a susceptor 208, a flow channel 204, an exhaust port 230, a zone heater 207, and a controller 28.

Hereinafter, in the HVPE apparatus 200, a region close to the supply source of each gas will be referred to as “upstream”, and a region close to the exhaust port 230 will be referred to as “downstream”. A gas containing gallium chloride (GaCl) gas as a group III source gas and ammonia (NH₃) gas as a nitrogen source gas is also referred to as a “source gas”.

As shown in FIG. 2, the airtight container 203 contains, for example, quartz. A film deposition chamber 201 is provided in the airtight container 203.

The susceptor 208 is provided in the film deposition chamber 201 and is configured to hold the seed substrate 10. The susceptor 208 is connected to a rotation shaft 215 of a rotation mechanism 216, and is configured to be able to rotate the seed substrate 10 in a circumferential direction (around the central axis of the susceptor 208 as a center of rotation).

The flow channel 204 is provided in the film deposition chamber 201 and is configured to form a gas flow path to the seed substrate 10 in the film deposition chamber 201. The flow channel 204 contains quartz, similarly to airtight container 203. The flow channel 204 has an opening (reference numeral not shown) through which the seed substrate 10 on the susceptor 208 is exposed in the flow channel 204.

The flow channel 204 has, from one end to the middle of the airtight container 203, for example, a group III source gas line 232a, a dopant gas line 232b, an NH₃ gas line 232c, and a carrier gas line 232d. The group III source gas line 232a, the dopant gas line 232b, the NH₃ gas line 232c, and the carrier gas line 232d each has a flow rate controller (not shown) and a valve (not shown) upstream of the airtight container 203, and is configured to be able to control the flow rate of each gas.

The group III source gas line 232a is configured, for example, as a group III source gas supply system, to generate GaCl gas as a group III source gas and supply the GaCl gas toward the seed substrate 10 on the susceptor 208. Specifically, the group III source gas line 232a has, for example, a gas generation vessel 233a. The gas generation vessel 233a accommodates a gallium (Ga) melt in the film deposition chamber 201. Hydrogen chloride (HCl) gas is supplied to the gas generation vessel 233a from the upstream of the group III source gas line 232a. In the gas generation vessel 233a, GaCl gas is generated by a reaction between HCl gas and Ga melt. The GaCl gas thus generated is supplied toward the seed substrate 10 held on the susceptor 208.

The dopant gas line 232b is configured, for example, as a dopant gas supply system, to supply a hydrocarbon gas as a dopant gas toward the seed substrate 10 on the susceptor 208. Examples of the dopant gas include methane (CH₄) gas, ethylene (C₂H₄) gas, and propane (C₃H₈) gas.

The dopant gas line 232b has, for example, a gas cylinder (gas supply source) filled with a dopant gas and a diluent gas that dilutes the dopant gas. The dopant gas line 232b is configured to be able to supply the dopant gas together with the diluent gas toward the seed substrate 10 in a state where the dopant gas and the diluent gas are sufficiently mixed. This allows the dopant gas to be reliably supplied toward the seed substrate 10.

The diluent gas flowing through the dopant gas line 232b may be, for example, N₂ gas or a mixture of N₂ gas and H₂ gas. As will be described later, in this embodiment, the ratio of the flow rate of N₂ gas contained in the diluent gas to the total flow rate of the diluent gas is preferably, for example, 80% or more.

The dopant gas line 232b may, for example, include multiple gas cylinders filled with different dopant gases. The gas cylinder used in the carbon coating formation step S100 and the gas cylinder used in the crystal layer growth step S400 may be different.

The dopant gas in the gas cylinder of the dopant gas line 232b does not need to be diluted with a diluent gas. For example, a diluent carrier gas line that supplies a diluent gas that dilutes the dopant gas may be provided separately from the dopant gas line 232b.

The NH₃ gas line 232c serves as an NH₃ gas supply system and is configured to supply NH₃ gas as an N source gas toward the seed substrate 10 on the susceptor 208.

The carrier gas line 232d serves as a carrier gas supply system and is configured to supply a carrier gas toward the seed substrate 10 on the susceptor 208. As described above, the carrier gas is the gas that flows through the flow channel 204 at a highest flow rate. The carrier gas may be, for example, N₂ gas or a mixture of N₂ gas and H₂ gas. As will be described later, the ratio of the flow rate of N₂ gas contained in the carrier gas to the total flow rate of the carrier gas is, for example, 80% or more.

Gases are supplied along (i.e., horizontally) the main surface 10s of the seed substrate 10 through the group III source gas line 232a, dopant gas line 232b, NH₃ gas line 232c, and carrier gas line 232d. The gas flow in the crystal layer growth step S400 will be described later.

In this embodiment, similarly to the above-described <Findings obtained by the inventors>, the component including the source gas and the carrier gas supplied into flow channel 204 is also referred to as a “source gas component (white arrow).” The component including the dopant gas and the diluent gas supplied into flow channel 204 is also referred to as a “dopant gas component (black arrow).”

On the other hand, the exhaust port 230 is provided at the other end of the airtight container 203 and is configured to exhaust the inside of the film deposition chamber 201. The exhaust port 230 is connected to, for example, a pump or a blower (not shown).

The zone heater 207 is provided on the outer periphery of the airtight container 203 and is configured to heat the inside of the airtight container 203 to a desired temperature. The zone heater 207 is divided into a plurality of zones, for example, a zone heater 207u and a zone heater 207d. A temperature sensor (not shown) for measuring the temperatures at various parts in the deposition chamber 201 are provided in the airtight container 203. The zone heaters 207u and 207d are adjusted based on the temperatures of the various parts in the airtight container 203, measured by the temperature sensor.

Specifically, the temperature of the group III source gas line 232a near the gas generation vessel 233 a is maintained at, for example, 700° C. or more and 900° C. or less, or 800° C. or more and 900° C. or less by the zone heater 207u. Thus, GaCl gas is generated by the reaction between the HCl gas and the Ga melt.

The temperature near the susceptor 208 is maintained by the zone heater 207d, at a growth temperature (990° C. or higher and 1120° C. or lower, preferably 1020° C. or higher and 1100° C. or lower) as will be described later.

Each component included in the HVPE apparatus 200 is connected to a controller 280 configured as a computer. The controller 280 is configured to control the above-described gas supply system, the zone heater 207, etc. The processing procedures and processing conditions described below are controlled by a program executed by the controller 280.

### S100: Carbon Coating Formation Step

Prior to the crystal layer growth step S400, the carbon coating formation step S100 is first performed as the above-described novel manufacturing method (A). That is, in a heated flow channel 204, by flowing the hydrocarbon gas through the dopant gas line 232b using the HVPE apparatus 200 shown in FIG. 2, a carbon coating 204a is formed on at least a part of the inner surface of a high temperature region of the flow channel 204, including at least a part of the dopant gas line 232b.

As a specific procedure for the carbon coating formation step S100, first, the inside of the film deposition chamber 210 is made airtight with the seed substrate 10 not placed on the susceptor 208. At this stage, the Ga melt does not have to be contained in the gas generation vessel 233a, or conversely, the Ga melt may be contained in the gas generation vessel 233a. In this state, the carrier gas is supplied into the film deposition chamber 201 from the carrier gas line 232d, while heating the inside of the film deposition chamber 201.

When the temperature inside of the film deposition chamber 201 reaches a predetermined temperature and the atmosphere inside of the film deposition chamber 201 becomes a predetermined atmosphere, the hydrocarbon gas is supplied from the dopant gas line 232b. This allows a thin film containing C (thin film composed of C) to be formed as the carbon coating 204a on the inner surface of the high temperature region of the flow channel 204 including at least a part of the dopant gas line 232b. The carbon coating 204a can suppress decomposition of the quartz that constitutes the flow channel 204, and can suppress the release of Si, O, etc., from the quartz into the film deposition chamber 201.

At this time, the hydrocarbon gas supplied from the dopant gas line 232b may be the same as the dopant gas supplied in the crystal layer growth step S400 described later, or may be a hydrocarbon gas different from the dopant gas.

The hydrocarbon gas supplied from the dopant gas line 232b may be, for example, an unsaturated hydrocarbon gas containing a small amount of H atoms. An example of the unsaturated hydrocarbon gas is ethylene (C₂H₄) gas.

At this time, the dopant gas flowing from the dopant gas line 232b in the carbon coating formation step S100 may be 100% hydrocarbon gas.

At this time, the HCl gas and NH₃ gas are not supplied from the group III source gas line 232a and the NH₃ gas line 232c, respectively.

At this time, the temperature near the dopant gas line 232b and the temperature near the susceptor 208 are set to 700° C. or higher, and the temperature which is the same as the growth temperature in the crystal layer growth step S400 described later, respectively. Thus, the carbon coating 204a can be formed on the inner surface of high temperature region of 700° C. or higher, that is, the region in the dopant gas line 232b and the region of the flow channel 204 near the susceptor 208.

Specifically, the conditions for the carbon coating formation step S100 are set as follows, for example.
Formation temperature: 1000° C.
Carrier gas flow rate: 25 L/min
Flow rate of the unsaturated hydrocarbon gas (100% C₂H₄ gas): 0.02 L/min

At this time, the thickness of the carbon coating 204a is, for example, 10 μm or more and 1000 μm or less, or 100 μm or more and 500 μm or less. By setting the thickness of the carbon coating 204a to 10 μm or more, or 100 μm or more, the release of Si, O, etc., from the quartz that constitutes the flow channel can be reliably suppressed. On the other hand, by setting the thickness of the carbon coating 204a to 1000 μm or less, or 500 μm or less, the occurrence of cracks in the carbon coating 204a can be suppressed.

### S200: Seed Substrate Preparation Step

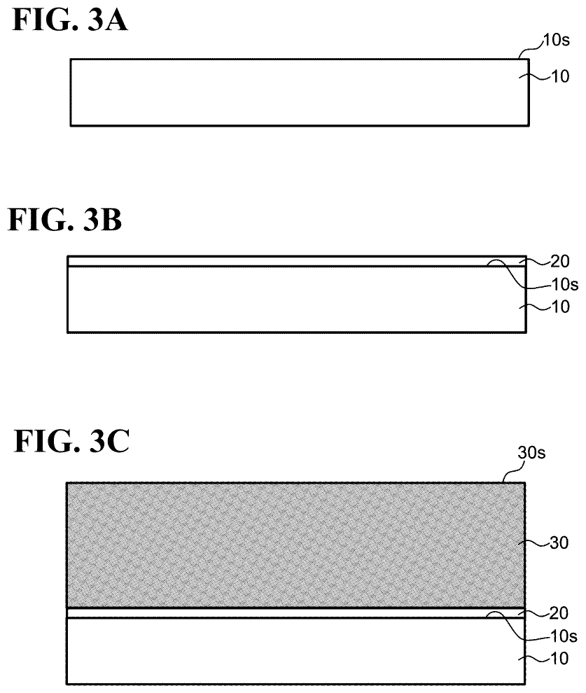

On the other hand, as shown in FIG. 3A, the seed substrate 10 including (composed of) group III nitride crystal (single crystal) is prepared. In this embodiment, for example, a GaN freestanding substrate is prepared as the seed substrate 10. The seed substrate 10 can be fabricated by, for example, a Void-Assisted Separation (VAS) method.

The diameter of the seed substrate 10 is, for example, 50 mm (2 inches) or more, or 100 mm (4 inches) or more. The thickness of the seed substrate 10 is, for example, 300 μm or more and 1 mm or less.

The seed substrate 10 has a main surface (crystal growth surface) 10s. The main surface 10s of the seed substrate 10 is, for example, mirror-finished. The root-mean-square roughness (RMS) of the main surface 10s of the seed substrate 10 is, for example, less than 1 nm.

In this embodiment, the low-index crystal plane closest to the main surface 10s is, for example, the c-plane (+c-plane) over an entire main surface 10s. That is, the seed substrate 10 does not have a polarity inversion domain (an inversion domain). Here, the “low-index crystal plane closest to the main surface 10s” means the low-index crystal plane that has a smallest angle with respect to the main surface 10s.

In this embodiment, the c-plane of the seed substrate 10 may be inclined with respect to main surface 10s. In this case, the c-axis of the seed substrate 10 may be inclined at a predetermined off-angle with respect to the normal on main surface 10s. The size of the off-angle at the center of the main surface 10s of the seed substrate 10 may be, for example, greater than 0° and equal to or less than 1°.

In this embodiment, the c-plane of the seed substrate 10 is curved, for example, into a concave spherical shape with respect to the main surface 10s. The radius of curvature of the c-plane of the seed substrate 10 is, for example, 3 m or more. The radius of curvature of the c-plane of the seed substrate 10 may be, for example, 150 m or less.

The (average) etch pit density when the main surface 10s of the seed substrate 10 is etched with an alkaline etching solution is, for example, 5×10⁶ cm⁻² or less. The method for measuring the etch pit density will be described later in the examples.

The seed substrate 10 does not include, at least in main surface 10s, any region that has been grown with a facet other than the c-plane as a growth plane. Therefore, the seed substrate 10 does not have any region where dislocations are locally concentrated. Specifically, when the main surface 10s of the seed substrate 10 is etched with an alkaline etching solution and the main surface 10s of the seed substrate 10 is observed in a field of view of 127 μm×95.3 μm to determine an etch pit density, no region (dislocation-concentrated region) is present where the etch pit density exceeds 1×10⁷ cm⁻².

### S300: Initial Layer Growth Step (Initial Step, Non-Doped Layer Formation Step)

After the seed substrate 10 is prepared, the initial layer growth step S300 is performed by the HVPE method using the above-described HVPE apparatus 200.

As a specific procedure for the initial layer growth step S140, after the carbon coating formation step S100, first, the HVPE apparatus 200 is opened to the atmosphere, and a Ga melt is placed in the gas generation vessel 233a. As described above, in the carbon coating formation step S100, the Ga melt may be placed in advance in the gas generation vessel 233a. Then, the seed substrate 10 is placed on the susceptor 208 in the HVPE apparatus 200. The Ga melt may be contained and the seed substrate 10 may be placed without opening the HVPE apparatus 200 to the atmosphere via a load lock. After the seed substrate 10 is placed on the susceptor 208, the susceptor 208 is rotated, and a carrier gas is supplied into the film deposition chamber 201 from the carrier gas line 232d while heating the inside of the film deposition chamber 201. Then, when the temperature inside of the film deposition chamber 201 reaches a desired growth temperature and the atmosphere inside of the film deposition chamber 201 becomes a desired atmosphere, GaCl gas and NH₃ gas are supplied as source gases from the group III source gas line 232a and the NH₃ gas line 232c to the main surface 10s of the heated seed substrate 10. At this time, the dopant gas is not supplied from the dopant gas line 232b.

As a result, as shown in FIG. 3B, GaCl gas reliably reaches the main surface 10s of the seed substrate 10 before the dopant gas, and the initial layer 20 including (composed of) C-free group III nitride semiconductor crystal (e.g., a non-doped GaN single crystal) is epitaxially grown on the main surface 10s of the seed substrate 10. At this time, the initial layer 20 is grown (step flow growth) over an entire main surface 10s of the seed substrate 10, with the c-plane as a growth plane without generating any facet other than the c-plane. Thus, the surface of the initial layer 20 is mirror-finished. The “mirror-finished surface” herein refers to a surface in which a maximum difference in height between adjacent concaves and convexes is equal to or less than a wavelength of visible light.

In this way, by allowing the C-free initial layer 20 to grow on the main surface 10s of the seed substrate 10 prior to the crystal layer growth step S400 described below, it is possible to prevent only C from adhering to a part of the main surface 10s of the seed substrate 10 at the initial stage of the growth of the crystal layer 30 in the crystal layer growth step S400. Thus, a three-dimensional growth of the crystal layer 30 can be suppressed.

In the initial layer growth step S190, the growth conditions are set, for example, as follows.
Growth temperature: 990° C. or more and 1120° C. or less, preferably 1020° C. or more and 1100° C. or less
V/III ratio: 1 or more and 10 or less, preferably 1 or more and 5 or less
Growth pressure: 90 to 105 kPa, preferably 90 to 95 kPa
GaCl gas partial pressure: 1.5 to 15 kPa
Ratio of N₂ gas flow rate in the carrier gas to the total flow rate of the carrier gas: 80% or more and 100% or less
The “growth temperature” is the temperature near the susceptor 208 controlled by the zone heater 207d. The “V/III ratio” is the ratio of the partial pressure of NH₃ gas to the partial pressure of GaCl gas as a group III source gas.

As described above, as long as the GaCl gas can reach the main surface 10s of the seed substrate 10 before the dopant gas, and the crystal growth can be initiated at a flat growth interface without irregularities (in a step-flow mode), the thickness of the initial layer 20 is not particularly limited.

### S400: Crystal Layer Growth Step (C-Doped Layer Growth Step)

After the growth of the initial layer 20 is completed, the seed substrate 10 is placed in the HVPE apparatus 200, and in this state, the following crystal layer growth step S400 is performed while supply of the HCl gas to the Ga line, supply of the NH₃ gas, and heating of the film deposition chamber 201 with the zone heater 207 are continued.

In the crystal layer growth step S400, as shown in FIG. 3C, the crystal layer 30 including (composed of) GaN crystal containing C is epitaxially grown above the main surface 10s of the seed substrate 10 (on the initial layer 20) by the HVPE method.

As a specific procedure for the crystal layer growth step S400, GaCl gas, NH₃ gas, and the hydrocarbon gas as a dopant gas are supplied to the heated seed substrate 10 from the group III source gas line 232a, the dopant gas line 232b, and the NH₃ gas line 232c through the flow channel 204 having the carbon coating 204a formed on the inner surface thereof. Thus, the crystal layer 30 including (composed of) GaN crystal containing C can be epitaxially grown.

In this embodiment, as described above, by allowing the crystal layer 30 to grow in a state where the carbon coating 204a is formed on the inner surface of the flow channel 204, the release of Si and O originating from the quartz that constitutes the flow channel 204 and the release of various impurities contained in the quartz, into the film deposition chamber 201 can be prevented. Thus, Si and O originating from the quartz, and various impurities contained in the quartz, can be suppressed from being mixed into the crystal layer 30.

In this embodiment, as described above, by allowing the crystal layer 30 to grow in a state where the carbon coating 204a is formed on the inner surface of the flow channel 204, the absorption of infrared rays from the zone heater 207 can be improved in the area where the carbon coating 204a is formed, thereby improving heating efficiency. Thus, the decomposition efficiency of the hydrocarbon gas used as a dopant gas can be improved, thereby allowing C to be reliably incorporated into the crystal layer 30.

Further, in this embodiment, as described above, by allowing the crystal layer 30 to grow in a state where the carbon coating 204a is formed on the inner surface of the flow channel 204, the catalytic effect of the carbon coating 204a, which promotes the decomposition of hydrocarbon gas, can be obtained in the high-temperature region of the flow channel 204, including at least a part of the dopant gas line 232b on which the carbon coating 204a is formed, where the temperature reaches 700° C. or higher. Due to the catalytic effect of the carbon coating 204a as well, the decomposition efficiency of the hydrocarbon gas used as a dopant gas can be improved.

At this time, in this embodiment, as the above-described novel manufacturing method (B), the hydrocarbon gas as a dopant gas is supplied to the seed substrate 10 from the dopant gas line 232b in the flow channel 204 together with the diluent gas containing 80% or more of N₂ gas. That is, the ratio of the flow rate of N₂ gas contained in the diluent gas to the total flow rate of the diluent gas is 80% or more and 100% or less. This allows the specific gravity of the dopant gas component to approach the specific gravity of the source gas component containing a large amount of N₂ gas as a carrier gas. By setting the difference to be small in the specific gravity of gases, deviation of the dopant gas component from the seed substrate 10 can be suppressed as shown in FIG. 13. That is, the dopant gas can sufficiently reach the seed substrate 10. As a result, C can be reliably incorporated into the crystal layer 30. Further, the amount of C incorporated into the crystal layer 30 can be uniform in the plane and can be uniform in the thickness direction.

Further, at this time, in this embodiment, as the above-described novel manufacturing method (C), the crystal layer 30 is grown (step flow growth) over the entire main surface 10s of the seed substrate 10, with the c-plane as a growth plane, without generating any facet other than the c-plane.

Here, a case where the crystal layer 30 is grown by generating a facet other than the c-plane on the surface of the crystal layer 30 will be described. The “facet other than the c-plane” referred to here includes, for example, {11-2m} and {1-10n}. Here, m and n are integers other than 0. Such a region that has been grown with the facet other than the c-plane as a growth plane is more likely to incorporate oxygen (O) than a region that has been grown with the c-plane as a growth plane. Conversely, the region that has been grown with the facet other than the c-plane as a growth plane is less likely to incorporate C.

In contrast, in this embodiment, by allowing the crystal layer 30 to grow (step flow growth) over the entire main surface 10s of the seed substrate 10 with the c-plane as a growth plane, the occurrence of any facet other than the c-plane on the surface of the crystal layer 30 can be suppressed. Thus, the incorporation of O as an n-type impurity due to the facet other than the c-plane in the crystal layer 30, can be suppressed. C can be efficiently incorporated into the crystal layer 30 from the c-plane as a growth plane. Further, the amount of C incorporated into the crystal layer 30 can be uniform in the plane and can be uniform in the thickness direction.

In the crystal layer growth step S400, examples of the hydrocarbon gas supplied from the dopant gas line 232b include methane (CH₄) gas, ethylene (C₂H₄) gas, propane (C₃H₈) gas, etc.

In this embodiment, the hydrocarbon gas supplied in the crystal layer growth step S400 may be, for example, an unsaturated hydrocarbon gas containing a small amount of H atoms. The unsaturated hydrocarbon gas is ethylene (C₂H₄) gas, etc. Thus, the incorporation of H originating from the hydrocarbon gas into the crystal layer 30 can be suppressed.

Specific growth conditions for the crystal layer growth step S400 are set, for example, as follows.
Growth temperature: 990° C. or more and 1120° C. or less, preferably 1020° C. or more and 1100° C. or less
Growth pressure: 90 to 105 kPa, preferably 90 to 95 kPa
GaCl gas partial pressure: 1.5 to 15 kPa
V/III ratio: 1 or more and 10 or less, preferably 1 or more and 5 or less
Ratio of the flow rate of N₂ gas in the carrier gas to the total flow rate of the carrier gas: 80% or more and 100% or less
Ratio of hydrocarbon gas partial pressure to GaCl gas partial pressure: 1×10⁻³ or more and 2 or less
Ratio of the flow rate of N₂ gas contained in the diluent gas to the total flow rate of the diluent gas: 80% or more and 100% or less
The growth conditions other than those described above in the crystal layer growth step S400 may be the same as or different from the growth conditions in the initial layer growth step S190.

The thickness of the crystal layer 30 is set to, for example, 300 μm or more and 10 mm or less. With this 300 μm or more thickness of the crystal layer 30, at least one substrate 50 can be sliced from the crystal layer 30 in the slicing step S500 described below. On the other hand, with this 10 mm or less thickness of the crystal layer 30, the occurrence of cracks in the crystal layer 30 can be suppressed.

The crystal layer 30 is formed by the crystal layer growth step S400 described above.

As described above, the steps from the initial layer growth step S190 to the crystal layer growth step S400 are performed consecutively in the same HVPE apparatus 200 without exposing the seed substrate 10 to the atmosphere. Thus, an unintended high oxygen concentration region can be suppressed from being formed at the interface between the initial layer 20 and the crystal layer 30.

After the growth of the crystal layer 30 is completed, the supply of HCl gas to the group III source gas line 232a and the supply of the dopant gas to the dopant gas line 232b are stopped, while the supply of the NH₃ gas is continued.

Then, as described above, the heating of the inside of the film deposition chamber 201 by the zone heater 207 is stopped, while the supply of the NH₃ gas is continued. After the temperature inside of the film deposition chamber 201 drops to 500° C. or less, the supply of the NH₃ gas is stopped, the atmosphere inside of the film deposition chamber 201 is replaced with N₂ gas, and the pressure inside of the film deposition chamber 201 is returned to the atmospheric pressure. Thereafter, the stack including the crystal layer 30 is unloaded from the HVPE apparatus 200.

### S500: Slicing Step

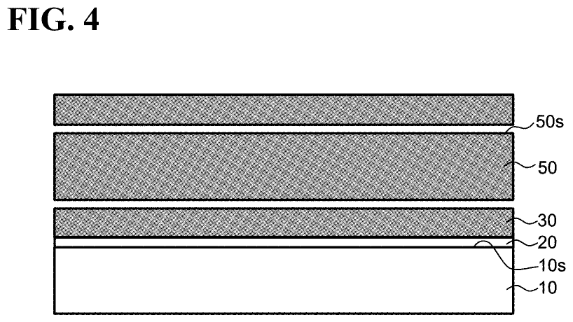

Next, as shown in FIG. 4, the crystal layer 30 is sliced along a cutting plane that is approximately parallel to the surface of the crystal layer 30 using, for example, a wire saw. Thus, at least one gallium nitride crystal substrate 50 (also referred to as a substrate 50) is formed. At this time, the thickness of the substrate 50 is set to, for example, 300 μm or more and 700 μm or less.

### S600: Polishing Step

Next, both surfaces of the substrate 50 are polished using a polishing device. At this time, a final thickness of the substrate 50 is set to, for example, 250 μm or more and 650 μm or less.

Through the above steps S100 to S600, the substrate 50 according to this embodiment is manufactured.

### Fabrication Step of a Semiconductor Stack and a Fabrication Step of a Semiconductor Device

After the substrate 50 is manufactured, for example, a semiconductor functional layer including (composed of) group III nitride crystal is epitaxially grown on the substrate 50 to fabricate a semiconductor stack. After the semiconductor stack is fabricated, the semiconductor stack is shaped as required for a semiconductor device, and electrodes, etc., are formed on the semiconductor stack. Thereafter, the semiconductor stack is diced to cut out chips of a predetermined size, thereby fabricating a semiconductor device.

### (2) Gallium Nitride Crystal Substrate (Freestanding Gallium Nitride Substrate)

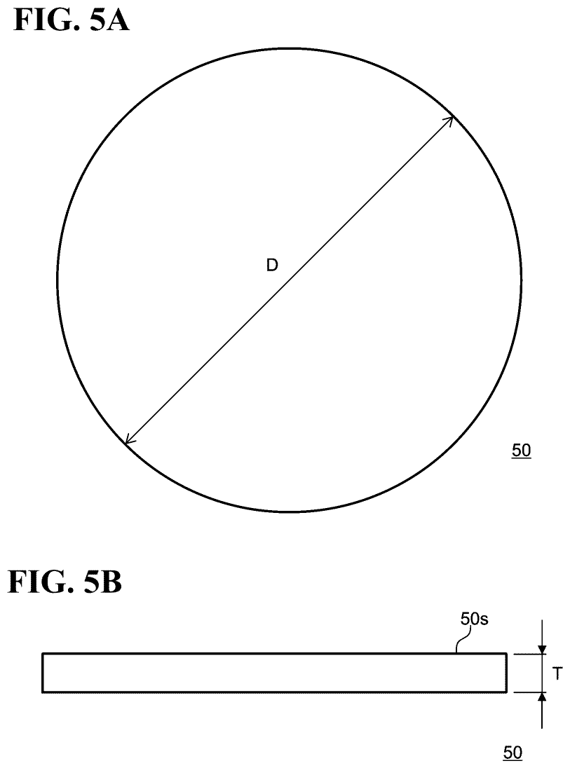

Next, a gallium nitride crystal substrate 50 according to this embodiment will be described with reference to FIGS. 5A and 5B. Hatching is omitted in FIG. 5B.

In this embodiment, the substrate 50 manufactured by the above-described manufacturing method is a free-standing substrate including (composed of), for example, gallium nitride crystal (single crystal).

The diameter D of the substrate 50 is, for example, 50 mm (2 inches) or more, or 100 mm (4 inches) or more. The thickness T of the substrate 50 is, for example, 300 μm or more and 1 mm or less.

The substrate 50 has, for example, a main surface 50s. The main surface 50s of the substrate 50 is, for example, mirror-finished. The root mean square roughness RMS of the main surface 50s of the substrate 50 is, for example, less than 1 nm.

In this embodiment, the low-index crystal plane closest to the main surface 50s is, for example, the c-plane (+c-plane) over an entire main surface 50s. That is, the substrate 50 does not have an inversion domain. The term “low-index crystal plane closest to the main surface 50s” herein means a low-index crystal plane that has a smallest angle with respect to the main surface 50s, similarly to the definition of the c-plane of the seed substrate 10 described above.

At the center of the main surface 50s of the substrate 50, an off-angle is, for example, greater than 0° and equal to or less than 1°, which is an angle that the c-axis forms with respect to the normal at the center of the main surface 50s.

### Impurity Concentration

The impurity concentration in the substrate 50 is measured, for example, by secondary ion mass spectrometry (SIMS). The impurity concentration in the substrate 50 described below refers to an average value of the impurity concentrations in the substrate 50 measured by SIMS in a region from a depth of 0.25 μm to 5 μm on the main surface 50s.

In this embodiment, the most abundant impurity element (dopant element) in the substrate 50 is C.

In this embodiment, by the above-described novel manufacturing methods (A) to (C), C is efficiently incorporated into the substrate 50 while preventing impurity elements other than C from being mixed in.

Specifically, the C concentration in the substrate 50 (hereinafter also referred to as [C]) is, for example, 2×10¹⁷ cm⁻³ or more and 3×10¹⁹ cm⁻³ or less. The C concentration in the substrate 50 may be, for example, 2×10¹⁷ cm⁻³ or more and 2.5×10¹⁸ cm⁻³ or less, or the C concentration in the substrate 50 may be, for example, 4 ×10¹⁷ cm-3 or more and 2×10¹⁹ cm⁻³ or less. The relationship between the C concentration and the resistivity will be described later.

In this embodiment, by the above-described novel manufacturing method (A), Si and O originating from the quartz that constitutes the flow channel 204 is suppressed from being mixed into the substrate 50.

Specifically, the Si concentration (hereinafter also referred to as [Si]) in the substrate 50 is lower than the C concentration in the substrate 50. The Si concentration in the substrate 50 is, for example, 4×10¹⁷ cm⁻³ or less, and more preferably less than 2×10¹⁷ cm⁻³.

Further, in this embodiment, in addition to the above-described novel manufacturing method (A), a novel manufacturing method (C) is used so that the substrate 50 does not include any region, in at least the main surface 50s, that has been grown with the facet other than the c-plane as a growth plane. More preferably, the substrate 50 does not include any region, over an entire substrate 50, that has been grown with the facet other than the c-plane as a growth plane. That is, the substrate 50 does not include a high oxygen concentration region as a facet growth region.

Specifically, the O concentration (hereinafter also referred to as [O]) in the substrate 50 (over the entire substrate 50) is lower than, for example, the Si concentration. Specifically, the O concentration in the substrate 50 is, for example, 1×10¹⁷ cm⁻³ or less, and preferably 4×10¹⁶ cm⁻³ or less.

In this embodiment, the substrate 50 is not actively doped with an element other than C that functions as a deep acceptor. Specifically, an iron (Fe) concentration (hereinafter also referred to as [Fe]) and a manganese (Mn) concentration (hereinafter also referred to as [Mn]) in the substrate 50 are each, for example, 1×10¹⁷ cm⁻³ or less, and preferably 7×10¹⁴ cm⁻³ or less.

In this embodiment, by the above-described novel manufacturing method (A), the decomposition efficiency of the hydrocarbon gas used as a dopant gas can be improved in the crystal layer growth step S400. Thus, the incorporation of H into the substrate 50 due to the undecomposed hydrocarbon gas can be suppressed.

Specifically, the H concentration in the substrate (hereinafter also referred to as [H]) is, for example, 1×10¹⁸ cm⁻³ or less, more preferably 5×10¹⁷ cm⁻³ or less, and further preferably 1×10¹⁷ cm⁻³ or less. Further, the ratio [H]/[C] of the H concentration to the C concentration in the substrate 50 is, for example, 0.7 or less, and preferably 0.6 or less.

In this embodiment, by the above-described novel manufacturing method (A), various impurities other than Si and O contained in the quartz are suppressed from being mixed into the substrate.

Specifically, the concentrations of other elements (hereinafter also referred to as “each element”) in the substrate 50 are below a lower detection limit of secondary ion mass spectrometry (SIMS), as follows.
[P]: 5×10¹⁴ cm⁻³ or less
[S]: 4×10¹³ cm⁻³ or less
[Cl]: 1×10¹⁴ cm⁻³ or less
[B]: 7×10¹⁴ cm⁻³ or less
[Na]: 2×10¹⁴ cm⁻³ or less
[Al]: 2×10¹⁵ cm⁻³ or less
[K]: 2×10¹³ cm⁻³ or less
[Ca]: 2×10¹³ cm⁻³ or less
[Ti]: 2×10¹⁴ cm⁻³ or less
[Cr]: 7×10¹³ cm⁻³ or less
[Ni]: 2×10¹⁵ cm⁻³ or less
[Ge]: 5×10¹⁴ cm⁻³ or less
[W]: 7×10¹⁵ cm⁻³ or less

### Insulation

In this embodiment, as described above, by the above-described novel manufacturing methods (A) to (C), the incorporation of the impurity elements other than C into the substrate 50 is suppressed, and C is efficiently incorporated. That is, the N site of GaN is reliably substituted with C. This contributes to the substrate 50 having a high resistivity (hereinafter also referred to as ρ) with a low C concentration. Further, in this embodiment, by the above-described novel manufacturing methods (B) and (C), the C concentration in the substrate 50 is uniform over an entire thickness. Thus, the substrate 50 has a uniformly high resistivity over its thickness.

### Resistivity

Specifically, the resistivity of the substrate 50 of this embodiment measured over an entire thickness of the substrate 50 at a temperature of 20° C. has the following characteristics. The method for measuring the resistivity will be described in the examples below.

For example, when [C] is in a range of 2×10¹⁷ cm⁻³ or more and 3×10¹⁹ cm⁻³ or less, the resistivity of the substrate 50 at a temperature of 20° C. is, for example, 1×10⁸ Ω·cm or more. This range of resistivity is a range that could not be achieved in Patent Document 1, as will be described in the examples below.

For example, when [C] is in a range of 2×10¹⁷ cm⁻³ or more and 2.5×10¹⁸ cm⁻³ or less, the resistivity of the substrate 50 at a temperature of 20° C. shows a monotonically increasing tendency. From this tendency, it is considered that in the range of [C], there is less C substituting for Ga site and less C interstitial atoms.

For example, when [C] is in a range of 4×10¹⁷ cm⁻³ or more and 2×10¹⁹ cm⁻³ or less, the resistivity of the substrate 50 at a temperature of 20° C. is 1×10¹² Ω·cm or more. This range of resistivity is a range that could not be achieved by a conventional C-doped substrate.

Further, in this embodiment, the substrate 50 satisfies, for example, formula (1).

$$ρ / [ C ] \geq 1 \times {10}^{- 8} \qquad ( 1 )$$

wherein ρ is the resistivity of the substrate 50 at a temperature of 20° C., measured in the unit of Ωcm.
[C] is the C concentration in the substrate 50, measured in the unit of cm⁻³.

When the substrate 50 satisfies the above formula (1), the ratio ρ/[C] of resistivity per unit C concentration becomes high. That is, C doped into the substrate 50 efficiently contributes to the high resistivity.

There is no limit in the upper limit of the resistivity of the substrate 50 at a temperature of 20° C. However, when [C] is in a range of 2×10¹⁷ cm⁻³ or more and 3×10¹⁹ cm⁻³ or less as in the examples described later, the resistivity of the substrate 50 at a temperature of 20° C. is 1×10¹⁴ Ωcm or less.

### Resistivity by the Van der Pauw Method

Specifically, the resistivity of the substrate 50 of this embodiment measured by the Van der Pauw method while varying the temperature, has the following characteristics.

In this embodiment, the ratio of the resistivity of the substrate 50 at a temperature of 327° C. to the resistivity of the substrate 50 at a temperature of 20° C. is, for example, 1×10⁻⁷ or more and 3×10⁻⁷ or less.

In this embodiment, the activation energy of C in the substrate 50 is, for example, 0.95 eV or more and 1.10 eV or less, which is determined based on the slope of the Arrhenius plot of resistivity of the substrate 50 in a range where the reciprocal of temperature is 0.0025 K⁻¹ or less (i.e., a range where the temperature is 400 K or higher). The activation energy of C in the substrate 50 is close to the activation energy of C as an acceptor in the GaN crystal, which is 0.9 eV, determined from a first principles calculation. This embodiment reveals that the N site can be reliably substituted with C that is incorporated into the substrate 50.

### Crystallinity

In this embodiment, since the substrate 50 has a high resistivity with a low C concentration, both high resistivity and good crystallinity are achieved.

The full width at half maximum (FWHM) of the (0002) diffraction of the substrate 50 obtained by X-ray rocking curve measurement is, for example, less than 60 arcsec. Further, the full width at half maximum of the (10-12) diffraction of the substrate 50 obtained by X-ray rocking curve measurement is, for example, less than 60 arcsec.

### C-Plane Warpage

In this embodiment, the c-plane of the substrate 50 follows the c-plane of the seed substrate 10 and is curved, for example, into a concave spherical shape with respect to the main surface 50s.

In this embodiment, as will be described later, the radius of curvature of the c-plane of the substrate 50 becomes small as [C] becomes high. However, the radius of curvature of the c-plane of the substrate 50 is equal to or greater than the radius of curvature of the c-plane of the seed substrate 10.

Specifically, for example, when [C] is in a range of 2×10¹⁷ cm⁻³ or more and 3×10¹⁹ cm⁻³ or less, the radius of curvature of the c-plane of the substrate 50 is 5 m or more, and preferably 6 m or more.

For example, when [C] is in a range of 2×10¹⁷ cm⁻³ or more and 2.5×10¹⁸ cm⁻³ or less, the radius of curvature of the c-plane of the substrate 50 is 8 m or more.

### Etch Pits, Dislocations

In this embodiment, by obtaining the substrate 50 from the crystal layer 30 grown thickly on the seed substrate 10, an average etch pit density when the main surface 50s of the substrate 50 is etched with an alkaline etching solution is equal to or less than an average etch pit density in the main surface 10s of the seed substrate 10. The etch pits referred to here are formed at positions where dislocations exist, and an etch pit density corresponds to a dislocation density. The method for measuring the etch pit density will be described later in the examples.

Specifically, the average etch pit density when the main surface 50s of the substrate 50 is etched with an alkaline etching solution is, for example, 5×10⁶ cm⁻² or less, and preferably 3×10⁶ cm⁻² or less.

In this embodiment, as described above, since the substrate 50 does not include any region that has been grown with the facet other than the c-plane as a growth plane, the substrate 50 does not have any region where dislocations are locally concentrated.

Specifically, when the main surface 50s of the substrate 50 is etched with an alkaline etching solution and the main surface 50s of the substrate 50 is observed in every field of view of 127 μm×95.3 μm to determine the etch pit density, no region (dislocation-concentrated region) is present where the etch pit density exceeds 1×10⁷ cm⁻².

### (3) Effects Obtained by This Embodiment

According to this embodiment, one or more of the following effects can be obtained.
(a) In this embodiment, prior to the crystal layer growth step S400, the above novel manufacturing method (A) is performed to form the carbon coating 204a on the inner surface of the high temperature region of the flow channel 204, including at least a part of the dopant gas line 232b. In the subsequent crystal layer growth step S400, by the carbon coating 204a, the decomposition of the quartz that constitutes the flow channel 204 can be suppressed, and the release of Si, O, etc., from the quartz into the film deposition chamber 201 can be suppressed. Thus, Si and O as n-type impurities can be suppressed from being mixed into the crystal layer 30 containing C. By thus suppressing the mixing of the n-type impurities that compensate for C, the substrate 50 having high resistivity with a low C concentration can be obtained from the crystal layer 30.
(b) In this embodiment, as described above, by allowing the crystal layer 30 to grow in a state where the carbon coating 204a is formed on the inner surface of the flow channel 204, absorption of infrared rays from the zone heater 207 can be improved in the area where the carbon coating 204a is formed, thereby improving heating efficiency. Thus the decomposition efficiency of the hydrocarbon gas used as a dopant gas can be improved. As a result, C can be reliably incorporated into the crystal layer 30. Specifically, the N site of GaN can be reliably substituted with C.
Further, since the decomposition efficiency of the hydrocarbon gas is improved, the incorporation of H into the crystal layer 30 due to the undecomposed hydrocarbon gas can be suppressed. Thus, the inactivation of C caused by H can be suppressed.
(c) In this embodiment, as described above, by allowing the crystal layer 30 to grow in a state where the carbon coating 204a is formed on the inner surface of the flow channel 204, the catalytic effect of the carbon coating 204a that promotes the decomposition of hydrocarbon gas can be obtained in the high temperature region of the flow channel 204 including at least a part of the dopant gas line 232b on which the carbon coating 204a is formed, where the temperature is 700° C. or higher. Owing to the catalytic effect of the carbon coating 204 a as well, the decomposition efficiency of the hydrocarbon gas used as a dopant gas can be improved. As a result, C can be reliably incorporated into the crystal layer 30, and the incorporation of H resulting from undecomposed hydrocarbon gas can be suppressed.
From the viewpoints of (b) and (c), the substrate 50 having high resistivity at a low C concentration can be obtained from the crystal layer 30.
(d) In the crystal layer growth step S400 of this embodiment, the above novel manufacturing method (B) is performed to supply the hydrocarbon gas as a dopant gas through the flow channel 204, from the dopant gas line 232b to the seed substrate 10 together with the diluent gas containing 80% or more of N₂ gas. This allows the specific gravity of the dopant gas component to approach the specific gravity of the source gas component containing a large amount of N₂ gas as a carrier gas. By setting the difference to be small in the specific gravity of gases, the deviation of the dopant gas component from the seed substrate 10 can be suppressed. That is, the dopant gas can reach the seed substrate 10 sufficiently. From this viewpoint as well, C can be reliably incorporated into the crystal layer 30. Further, the amount of C incorporated into the crystal layer 30 can be uniform in the plane and can be uniform in the thickness direction.
(e) In the crystal layer growth step S400 of this embodiment, the above new manufacturing method (C) is performed to allow the crystal layer 30 to grow (step flow growth) over the entire main surface 10s of the seed substrate 10, with the c-plane as a growth plane. By using the c-plane as a growth plane, the generation of any facet other than the c-plane on the surface of the crystal layer 30 can be suppressed. Thus, the incorporation of O as an n-type impurity due to the facet other than the c-plane in the crystal layer 30, can be suppressed. C can be efficiently incorporated into the crystal layer 30 from the c-plane as the growth plane. Further, the amount of C incorporated into the crystal layer 30 can be uniform in the plane and can be uniform in the thickness direction.
By (d) and (e), the C concentration in the substrate 50 can be uniform over an entire thickness. Thus, the substrate 50 having not only high resistivity with a low C concentration but also a uniformly high resistivity over its thickness, can be obtained.

### Other Embodiment

Although the embodiments of the present disclosure have been specifically described above, the present disclosure is not limited to the above-described embodiments and can be modified in various ways without departing from the spirit and scope of the present disclosure.

### EXAMPLES

Various experimental results that support the effects of the present disclosure will be described below. In the figures of the examples, “aEb” means “a×10^{b}.”

### (1) Manufacture of a Gallium Nitride Crystal Substrate of an Example

As an example, a number of gallium nitride crystal substrates with different C concentrations were fabricated under the following manufacturing conditions using a manufacturing method that applied (A) to (C) described in the above embodiment.

### Manufacturing Conditions for a Gallium Nitride Crystal Substrate of an Example

### Seed Substrate

Material: Undoped GaN
Manufacturing method: VAS method
Diameter: 101.6 mm (4 inches)
Thickness: 400 μm
Low-index crystal plane closest to the main surface: c-plane
No patterning, such as a mask layer, was applied to the main surface.
Radius of curvature of the c-plane: 5 m
Average etch pit density in the main surface: 4×10⁶ cm⁻²

### Carbon Coating Formation Step

Hydrocarbon gas: C₂H₄ gas
Thickness of the carbon coating: approximately 100 μm to 500 μm

### Crystal Layer Growth Step

Material: C-doped GaN crystal
Growth method: HVPE
Growth temperature: 1050° C.
Growth pressure: 95 kPa
GaCl gas partial pressure: 7 kPa
V/III ratio: 2
Ratio of N₂ gas flow rate in the carrier gas to the total flow rate of the carrier gas: 80%
Hydrocarbon gas: CH₄ gas or C₂H₄ gas
Ratio of N₂ gas flow rate in the diluent gas to the total flow rate of the diluent gas: 80%
Thickness of the crystal layer: 1000 μm

In the crystal layer growth step, the ratio of the partial pressure of the hydrocarbon gas to the partial pressure of the GaCl gas was adjusted by adjusting the flow rate of the hydrocarbon gas while keeping the partial pressure of the GaCl gas constant. A plurality of batches were performed with different ratios of hydrocarbon gas partial pressure/GaCl gas partial pressure, and crystal layers with different C concentrations were grown between the batches.

### Slicing Step and Polishing Step

Kerf loss during slicing: 200 μm
Double-sided polishing
Final thickness of the gallium nitride crystal substrate: 400 μm

### (2) Comparative Example

A gallium nitride crystal substrate of a comparative example was manufactured by reproducing the manufacturing method described in Patent Document 1. The manufacturing conditions in the comparative example were the same as those for the gallium nitride crystal substrate described as example 1 in Patent Document 1, except for the conditions for the seed substrate.

### Manufacturing Conditions for the Gallium Nitride Crystal Substrate in Patent Document 1 as a Comparative Example

### Seed Substrate

Material: Undoped GaN
Manufacturing method: Facet growth method (JP Patent Publication No. 2001-102307, hereafter referred to as a seed substrate document)
Diameter: 101.6 mm (4 inches)
Thickness: 400 μm
Low-index crystal plane closest to the main surface: c-plane
No patterning, such as a mask layer, was applied to the main surface.

### Carbon Coating Formation Step

Not performed as there is no particular description in Patent Document 1.

### Crystal Layer Growth Step

Material: C-doped GaN crystal
Growth method: HVPE
Growth temperature: 1050° C.
Growth pressure: 100 kPa
GaCl gas partial pressure: 0.5 kPa
V/III ratio: 40
Hydrocarbon gas: CH₄ gas
Diluent gas that dilutes the dopant gas: H₂ gas
Ratio of N₂ gas flow rate in the diluent gas to total flow rate of the diluent gas: 0%
Growth time for the crystal layer: 10 hours

### Slicing Step and Polishing Step

Double-sided polishing

Final thickness of the gallium nitride crystal substrate: 300μm

### (3) Evaluation

The gallium nitride crystal substrates of the example and comparative example were evaluated as follows.

### Secondary Ion Mass Spectrometry (SIMS)

SIMS was performed for the main surface of the gallium nitride crystal substrate.

### Resistivity Measured by Front and Back Contact

Some of the gallium nitride crystal substrates of the example had very high resistivities, making it difficult to measure their resistivity at a room temperature using a conventional Van der Pauw resistivity measuring device. Therefore, the resistivity of the gallium nitride crystal substrate at a temperature of 20° C. was measured using a front and back contact measurement type Hiresta UX (MCP-HT800) manufactured by Nitto Seiko Analytech Co., Ltd. As a specific procedure, the gallium nitride crystal substrate was first placed on a UFL table serving as a back electrode. In this state, a probe was brought into contact with the main surface of the gallium nitride crystal substrate, and a predetermined electric field was applied in the thickness direction of the gallium nitride crystal substrate. The resistivity of each gallium nitride crystal substrate was measured using this method. When measuring each gallium nitride crystal substrate, the center of the probe was positioned at the center of the main surface.

The measurement conditions are as follows.
Method: Front and back contact measurement (with guide ring)
Probe type: URS
Probe: Diameter of a center electrode φ5.9 mm, inner diameter of a guide ring φ11 mm
Applied voltage: 500 V (i.e., applied electric field of 1.25×10³ V/mm at 400 μm thickness)
Measurement method: Average of 10 measurements

### Resistivity by the Van der Pauw Method

To determine the temperature dependence of the resistivity, with four terminals positioned symmetrically around the center on the main surface of the gallium nitride crystal substrate, the resistivity of the gallium nitride crystal substrate was measured by a four-terminal Van der Pauw method while varying the temperature by heating the gallium nitride crystal substrate during measurement.

### X-Ray Rocking Curve Measurement 1

At the center of the main surface of the gallium nitride crystal substrate, an X-ray rocking curve measurement was performed for the (0002) diffraction of GaN constituting the gallium nitride crystal substrate, and an X-ray rocking curve measurement was performed for the (10-12) diffraction of GaN constituting the gallium nitride crystal substrate. As a result, the full width at half maximum (FWHM) of the (0002) diffraction of the gallium nitride crystal substrate and the full width at half maximum of the (10-12) diffraction of the gallium nitride crystal substrate were determined.

The X-ray rocking curve measurement was performed under the following conditions.
X-ray: monochromatic Cu Kα1 light obtained from the X-ray source via an X-ray mirror and two
Ge (220) crystals.
Goniometer radius: 420 mm
Entrance slit width: 0.1 mm
Receiving slit side: analyzer crystal

### X-Ray Rocking Curve Measurement 2

The X-ray rocking curve measurement for the (0002) diffraction of GaN constituting the gallium nitride crystal substrate was performed in the same manner as in X-ray rocking curve measurement 1, at a plurality of measurement points set at 5 mm intervals in the main surface of the gallium nitride crystal substrate, on a line passing through the center and along the m-axis direction, and on a line passing through the center and along the a-axis direction perpendicular to the m-axis.

As a result of the measurement, the peak angle ω at which the diffraction intensity is maximized was determined, which is the angle between the X-rays incident on the main surface of the gallium nitride crystal substrate and the main surface. Further, the above-described peak angle ω was plotted with respect to a position on the line on which each measurement point was placed, and the peak angle ω was approximated by a linear function of the position. The radius of curvature of the c-plane was determined from the reciprocal of the slope of the linear function.

### Etch Pit

The gallium nitride crystal substrate was immersed in a molten alkaline etching solution, which was a 1:1 mixture of potassium hydroxide (KOH) and sodium hydroxide (NₐOH), at a temperature of 470° C. for 20 minutes. Thus, the main surface of the gallium nitride crystal substrate was etched, to form etch pits on the main surface.

Next, the main surface of the gallium nitride crystal substrate on which the etch pits had been formed was observed in a field of view of 127 μm×95.3 μm using a scanning electron microscope (SEM). Thus, the etch pit density in the main surface of the gallium nitride crystal substrate was determined.

The average etch pit density in the main surface of the gallium nitride crystal substrate was determined, based on the etch pit density measured in a region including the center of the main surface of the gallium nitride crystal substrate and in four regions spaced 20 mm in radius from the center of the main surface and arranged in fourfold symmetry around the center of the main surface.

Further, the entire main surface of the gallium nitride crystal substrate was observed in every 127 μm×95.3 μm field of view to check for the presence or absence of regions where the etch pit density exceeded 1×10⁷ cm⁻² (dislocation-concentrated regions).

### (4) Results

A comparison will be made between the gallium nitride crystal substrate of the example manufactured under the above-described manufacturing conditions and the gallium nitride crystal substrate described in Patent Document 1 as a comparative example.

### Results for the Gallium Nitride Crystal Substrate of Patent Document 1 as a Comparative Example

The results for the gallium nitride crystal substrate of Patent Document 1, which serves as a comparative example, were as follows.
Minimum C concentration in the gallium nitride crystal substrate: 1×10¹⁸ cm⁻³
Distribution of the C concentration in the plane (maximum concentration/minimum concentration): 1.5
Resistivity of the gallium nitride crystal substrate: 1×10⁷ Ωcm or more, less than 1 ×10⁸ Ωcm
ρ/[C]: 1×10⁻¹¹ (Ωcm⁴) or more, 1×10⁻¹⁰ (Ωcm⁴) or less
Full width at half maximum of the (0002) diffraction obtained by X-ray rocking curve measurement: 60 arcsec
Average etch pit density: 1×10⁶ cm⁻²

As described above, the carbon coating formation step was not performed in the comparative example disclosed in Patent Document 1. In the comparative example, the diluent gas for diluting the dopant gas in the dopant gas line was H₂ gas. Therefore, in the comparative example, Si, O, etc., originating from the quartz were mixed into the gallium nitride crystal substrate. In the comparative example, C was less likely to be incorporated into the gallium nitride crystal substrate. Further, in the comparative example, H, which inactivates C, was incorporated into the gallium nitride crystal substrate due to undecomposed hydrocarbon gas. As a result, in the comparative example, the resistivity of the gallium nitride crystal substrate was less likely to increase relative to the C concentration. In the comparative example, the value of ρ/[C] was small, and C did not efficiently contribute to high resistivity.

Further, in the comparative example, although the crystal layer was grown while maintaining a flat surface, the seed substrate was obtained by facet growth. As described in the document of the seed substrate, dislocations remained concentrated during the facet growth step of obtaining the seed substrate. Therefore, when the main surface of the seed substrate was observed in every field of view of 127 μm×95.3 μm, regions (dislocation-concentrated regions) were present where the etch pit density exceeded 1×10⁷ cm⁻². Therefore, in the comparative example, the crystal layer grown on the seed substrate also followed the dislocations of the seed substrate and had regions where the etch pit density was more than 1×10⁷ cm⁻².

### Results Regarding the Gallium Nitride Crystal Substrate of the Example

The results obtained regarding the gallium nitride crystal substrates of the example will be described.

### Impurity Concentration

The impurity concentrations in the gallium nitride crystal substrate of the example were as follows:
[C]: 2×10¹⁷ cm⁻³ or more and 3×10¹⁹ cm⁻³ or less
[Si]: 4.9×10¹⁶ cm⁻³ or more and 3.0×10¹⁷ cm⁻³ or less
[O]: 8.0×10¹⁵ cm⁻³ or more and 5.5×10¹⁶ cm⁻³ or less
[Fe]: 7×10¹⁴ cm⁻³ or less
[Mn]: 7×10¹⁴ cm⁻³ or less

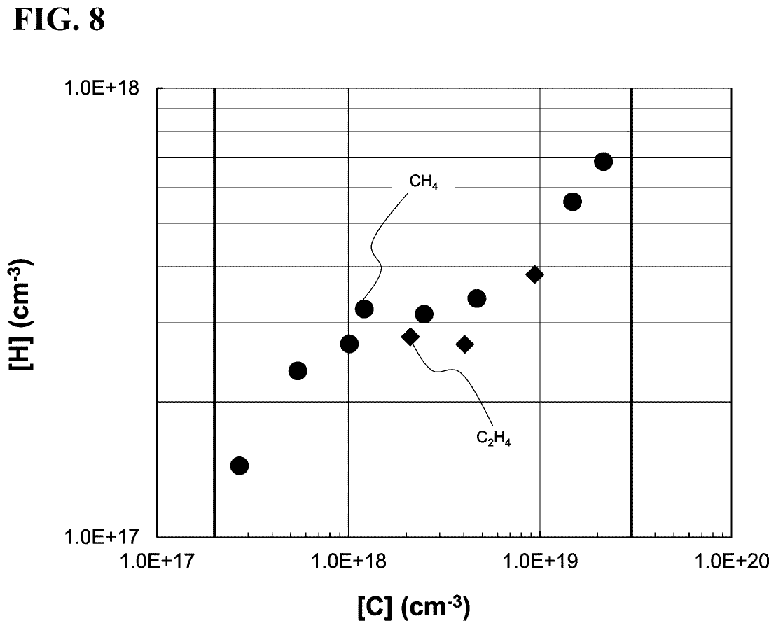

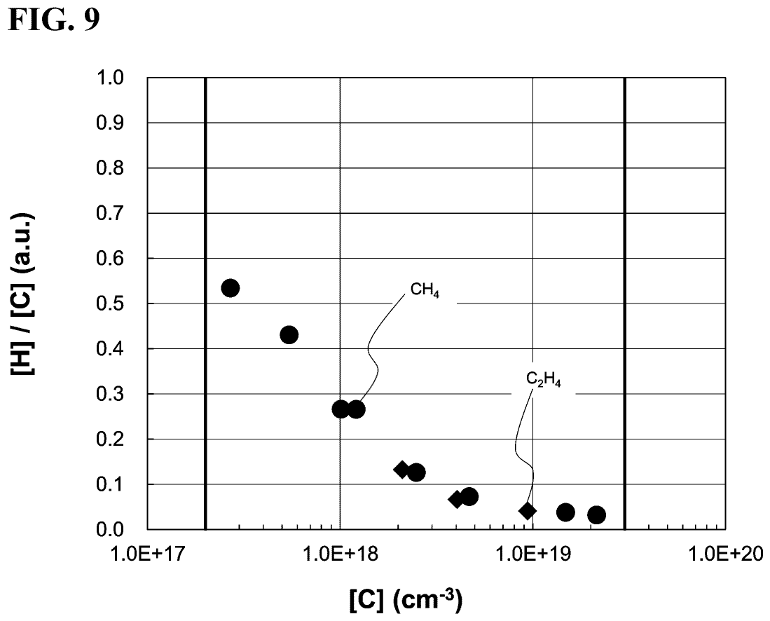

As shown in FIGS. 8 and 9, [H] in the gallium nitride crystal substrates of the example were as follows.
[H]: 1.4 ×10¹⁷ cm⁻³ or more and 6.9 ×10¹⁷ cm⁻³ or less
[H]/[C]: 0.032 or more and 0.53 or less

In addition, the contents of [P], [S], [Cl], [B], [Na], [Al], [K], [Ca], [Ti], [Cr], [Ni], [Ge], and [W] in the gallium nitride crystal substrate were equal to or less than a lower detection limit of SIMS described above.

### Resistivity

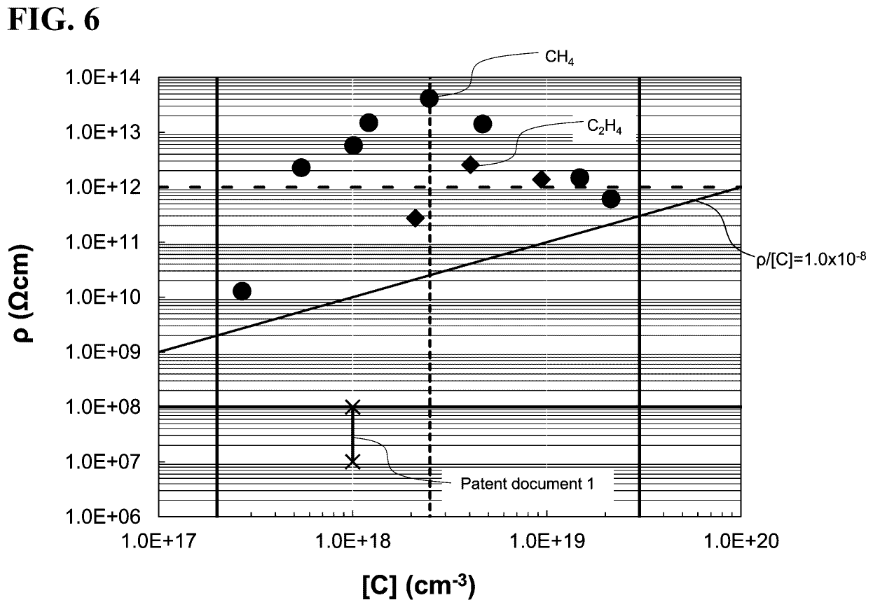

The resistivity of the gallium nitride crystal substrate of the example at a temperature of 20° C. is as shown in FIG. 6. As shown in FIG. 6, the resistivity of the gallium nitride crystal substrate of the example was higher than the resistivity of the gallium nitride crystal substrate of Patent Document 1, which serves as a comparative example.

Specifically, when [C] was in a range of 2×10¹⁷ cm⁻³ or more and 3×10¹⁹ cm⁻³ or less, the resistivity of the gallium nitride crystal substrate of the example at a temperature of 20° C. was 1×10⁹ Ω·cm or more.

When [C] is in a range of 2×10¹⁷ cm⁻³ or more and 2.5×10¹⁸ cm⁻³ or less, the resistivity of the gallium nitride crystal substrate of the example at a temperature of 20° C. showed a monotonically increasing trend.

When [C] is in a range of 4×10¹⁷ cm⁻³ or more and 2×10¹⁹ cm⁻³ or less, the resistivity of the gallium nitride crystal substrate of the example at a temperature of 20° C. was 1×10¹² Ω·cm or more.

Further, the gallium nitride crystal substrate of the example satisfied the above-described formula (1):

$$ρ / [ C ] \geq 1 \times {10}^{- 8} .$$

### Resistivity by the Van der Pauw Method

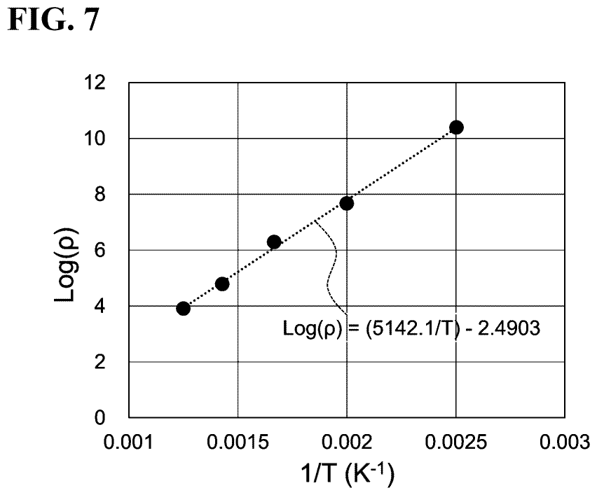

FIG. 7 shows the result of measuring the resistivity, by the Van der Pauw method, of the gallium nitride crystal substrate of the example in which [C] was 5.4×10¹⁷ cm⁻³ while varying the temperature. In FIG. 7, the ratio of the resistivity of the gallium nitride crystal substrate of the example at a temperature of 327° C. to the resistivity of the gallium nitride crystal substrate of the example at a temperature of 20° C. was 1×10⁻⁷ or more and 3×10⁻⁷ or less. The activation energy of C in the gallium nitride crystal substrate of the example was 1.02 eV, which was determined based on the slope of the Arrhenius plot of resistivity of the gallium nitride crystal substrate of the example in a range where the reciprocal of temperature is 0.0025 K⁻¹ or less.

As described above, in the example, it was confirmed that by using the above-described novel manufacturing methods (A) to (C), the gallium nitride crystal substrate having high resistivity ρ with low [C] could be reliably obtained.

### Crystallinity

The crystallinity of the gallium nitride crystal substrate of the example was better than that of the gallium nitride crystal substrate of the comparative example.

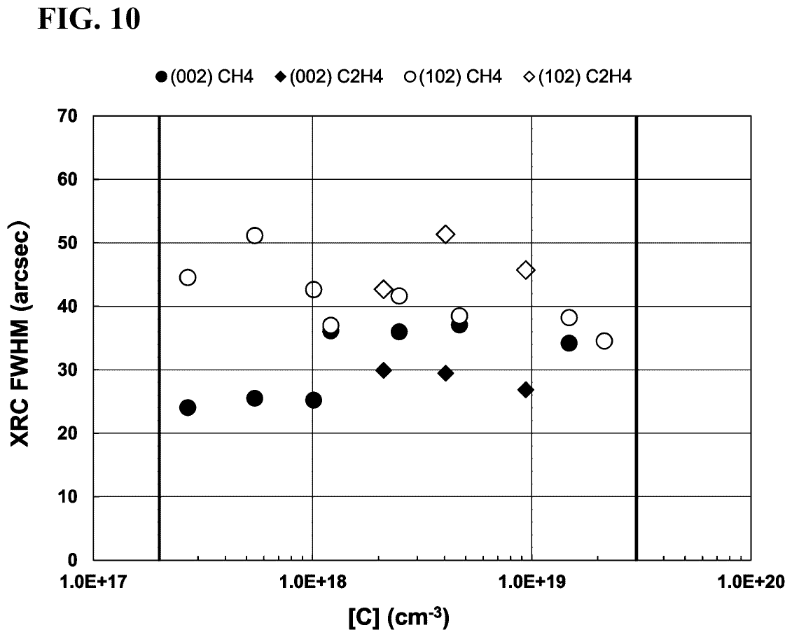

Specifically, as shown in FIG. 10, the full width at half maximum (FWHM) of the (0002) diffraction (referred to as (002) in the figure) of the gallium nitride crystal substrate of the example obtained by X-ray rocking curve measurement was less than 60 arcsec. Further, the full width at half maximum of the (10-12) diffraction (referred to as (102) in the figure) of the gallium nitride crystal substrate of the example obtained by X-ray rocking curve measurement was less than 60 arcsec.

In the example, it was confirmed that high resistivity ρ and good crystallinity were both achieved in the gallium nitride crystal substrate.

### Radius of Curvature of the C-Plane

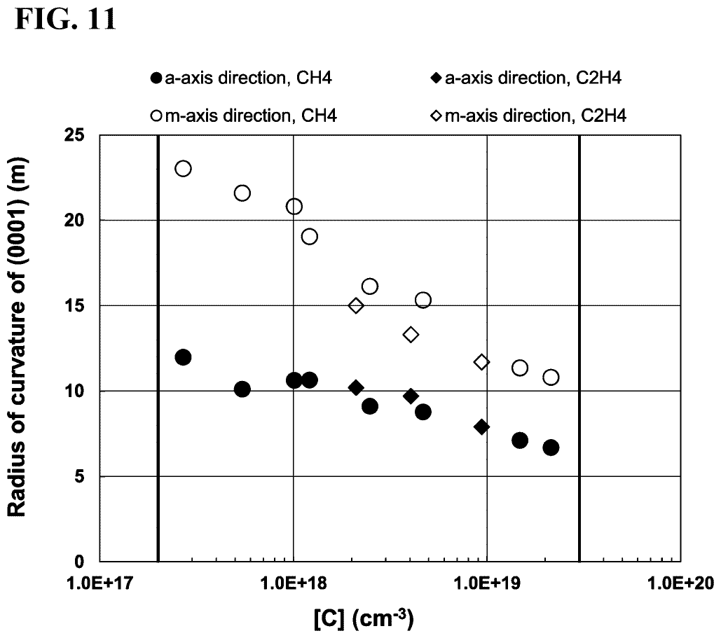

As shown in FIG. 11, the radius of curvature of the c-plane of the gallium nitride crystal substrate of the example was 6 m or more.

It was confirmed that the radius of curvature of the c-plane of the gallium nitride crystal substrate of the example could be larger than the radius of curvature of the c-plane of the seed substrate.

### Etch Pit Density

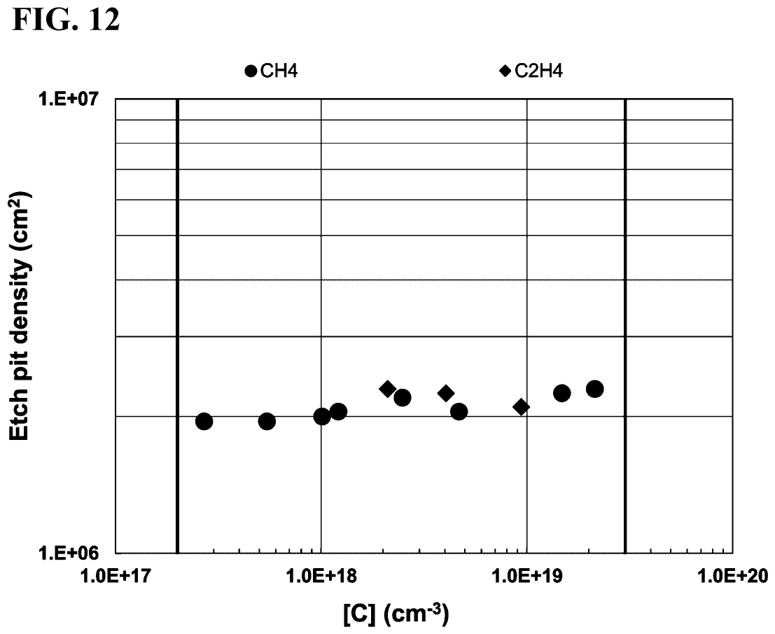

As shown in FIG. 12, the average etch pit density in the main surface of the gallium nitride crystal substrate of the example was 3×10⁶ cm⁻² or less.

Further, in the example, when the etch pit density was determined by observing the main surface of the seed substrate in every field of view of 127 μm×95.3 μm, no region (dislocation-concentrated region) was present where the etch pit density exceeded 1×10⁷ cm⁻².

In the example, it was confirmed that the gallium nitride crystal substrate was obtained that had a low etch pit density (i.e., dislocation density) over the entire main surface and no dislocation-concentrated region present therein.

### Supplementary Description

The following supplementary descriptions are provided regarding aspects of the present disclosure.

### Supplementary Description 1

A gallium nitride crystal substrate,
the gallium nitride crystal substrate having a main surface whose closest low-index crystal plane is (0001),
wherein an impurity element most abundant in the gallium nitride crystal substrate is carbon, and
a resistivity of the gallium nitride crystal substrate at a temperature of 20° C. is 1×10¹² Ωcm or more.

### Supplementary Description 2

A gallium nitride crystal substrate,
the gallium nitride crystal substrate having a main surface whose closest low-index crystal plane is (0001), and
containing carbon at a concentration of 2×10¹⁷ cm⁻³ or more and 3×10¹⁹ cm⁻³ or less,
wherein a resistivity of the gallium nitride crystal substrate at a temperature of 20° C. is 1×10⁸ Ωcm or more.

### Supplementary Description 3

The gallium nitride crystal substrate according to supplementary description 2, wherein the gallium nitride crystal substrate satisfies formula (1):

$$ρ / [ C ] \geq 1 \times {10}^{- 8} \qquad ( 1 )$$

wherein, ρ is the resistivity of the gallium nitride crystal substrate at a temperature of 20° C., measured in the unit of Ωcm, and

[C] is a carbon concentration in the gallium nitride crystal substrate, measured in the unit of cm⁻³.

### Supplementary Description 4

The gallium nitride crystal substrate according to any one of supplementary descriptions 1 to 3, wherein the carbon concentration in the gallium nitride crystal substrate is 2×10¹⁷ cm⁻³ or more and 2.5×10¹⁸ cm⁻³ or less.

### Supplementary Description 5

The gallium nitride crystal substrate according to any one of supplementary descriptions 1 to 4, wherein a silicon concentration in the gallium nitride crystal substrate is 4×10¹⁷ cm⁻³ or less, and more desirably less than 2×10¹⁷ cm⁻³.

### Supplementary Description 6

The gallium nitride crystal substrate according to any one of supplementary descriptions 1 to 5, wherein an oxygen concentration in the gallium nitride crystal substrate is lower than a silicon concentration.

### Supplementary Description 7

The gallium nitride crystal substrate according to any one of supplementary descriptions 1 to 6, wherein a hydrogen concentration in the gallium nitride crystal substrate is 1×10¹⁸ cm⁻³ or less, more preferably 5×10¹⁷ cm or less⁻³, and even more preferably 1×10¹⁷ cm⁻³ or less.

### Supplementary Description 8

The gallium nitride crystal substrate according to any one of supplementary descriptions 1 to 7, wherein a ratio of the hydrogen concentration to the carbon concentration in the gallium nitride crystal substrate is 0.7 or less.

### Supplementary description 9

The gallium nitride crystal substrate according to any one of supplementary descriptions 1 to 8, wherein an iron concentration and a manganese concentration in the gallium nitride crystal substrate are each 1×10¹⁷ cm⁻³ or less.

### Supplementary Description 10

The gallium nitride crystal substrate according to any one of supplementary descriptions 1 to 9, wherein a ratio of a resistivity of the gallium nitride crystal substrate at a temperature of 327° C. to a resistivity of the gallium nitride crystal substrate at a temperature of 20° C. is 1×10⁻⁷ or more and 3×10⁻⁷ or less.

### Supplementary Description 11

The gallium nitride crystal substrate according to any one of supplementary descriptions 1 to 10, wherein an activation energy of carbon in the gallium nitride crystal substrate is 0.95 eV or more and 1.10 eV or less, which is determined based on a slope of an Arrhenius plot of resistivity of the gallium nitride crystal substrate in a range where a reciprocal of temperature is 0.0025 K⁻¹ or less.

### Supplementary Description 12

The gallium nitride crystal substrate according to any one of supplementary descriptions 1 to 11, wherein the gallium nitride crystal substrate does not include, at least in the main surface, any region that has been grown with a facet other than (0001) as a growth plane.

### Supplementary Description 13

The gallium nitride crystal substrate according to any one of supplementary descriptions 1 to 12, wherein a full width at half maximum of (0002) diffraction of the gallium nitride crystal substrate obtained by X-ray rocking curve measurement is 60 arcsec or less.

### Supplementary Description 14

A gallium nitride crystal substrate,
the gallium nitride crystal substrate having a main surface whose closest low-index crystal plane is (0001),
wherein a resistivity of the gallium nitride crystal substrate at a temperature of 20° C. is 1×10¹² Ωcm or more, and
a full width at half maximum of a (0002) diffraction of the gallium nitride crystal substrate obtained by X-ray rocking curve measurement is 60 arcsec or less.

### Supplementary Description 15

A method for manufacturing a gallium nitride crystal substrate, the method including:
flowing hydrocarbon gas from a dopant gas line in a heated flow channel containing quartz, thereby forming a carbon coating on at least a part of an inner surface of a high temperature region of the flow channel, including at least a part of the dopant gas line; and
epitaxially growing a crystal layer including carbon-containing gallium nitride crystal above a seed substrate by supplying gallium chloride gas, nitrogen source gas, and hydrocarbon gas to the seed substrate, which is heated, through the flow channel having the carbon coating formed on the inner surface thereof, by an HVPE method.

### Supplementary Description 16

The method for manufacturing a gallium nitride crystal substrate according to supplementary description 15, wherein the forming the carbon coating includes forming the carbon coating on the inner surface of the high-temperature region where a temperature becomes 700° C. or higher.

### Supplementary Description 17

The method for manufacturing a gallium nitride crystal substrate according to supplementary description 15 or 16, wherein in the epitaxially growing the crystal layer, the hydrocarbon gas is supplied to the seed substrate from the dopant gas line in the flow channel together with a diluent gas containing 80% or more of nitrogen gas.

### Supplementary Description 18

The method for manufacturing a gallium nitride crystal substrate according to any one of supplementary descriptions 15 to 17, wherein in the epitaxially growing the crystal layer, the crystal layer is grown with (0001) as a growth plane without generating any facet other than (0001) over an entire main surface of the seed substrate.

### Supplementary Description 19

A gallium nitride crystal substrate manufacturing apparatus including:
an airtight container that accommodates a seed substrate;
a flow channel containing quartz and forming a gas flow path to the seed substrate in the airtight container;
a gas supply system that supplies gallium chloride gas, ammonia gas, and hydrocarbon gas to the seed substrate through the flow channel in the airtight container;
a heating unit that heats an inside of the airtight container; and
a control unit that controls the gas supply system and the heating unit so as to epitaxially grow a crystal layer composed of carbon-containing gallium nitride crystal above the seed substrate by supplying the gallium chloride gas, the ammonia gas, and the hydrocarbon gas to the heated seed substrate through the flow channel, by an HVPE method,
wherein the flow channel has an inner surface facing a side through which the gallium chloride gas, the ammonia gas, and the hydrocarbon gas flow; and
at least a part of the inner surface of a high temperature region of the flow channel, which includes at least a part of the gas supply system that supplies the hydrocarbon gas, is covered with a carbon coating.

What is claimed is:

1. A gallium nitride crystal substrate,
the gallium nitride crystal substrate having a main surface whose closest low-index crystal plane is (0001),
wherein an impurity element most abundant in the gallium nitride crystal substrate is carbon, and
a resistivity of the gallium nitride crystal substrate at a temperature of 20°C. is 1×10¹² Ωcm or more.

2. A gallium nitride crystal substrate,
the gallium nitride crystal substrate having a main surface whose closest low-index crystal plane is (0001), and
containing carbon at a concentration of 2×10¹⁷ cm⁻³ or more and 3×10¹⁹ cm⁻³ or less,
wherein a resistivity of the gallium nitride crystal substrate at a temperature of 20°C. is 1×10⁸ Ωcm or more.

3. The gallium nitride crystal substrate according to claim 2, wherein the gallium nitride crystal substrate satisfies formula (1):
$$ρ / [ C ] \geq 1 \times {10}^{- 8} \qquad ( 1 )$$
wherein, ρ is the resistivity of the gallium nitride crystal substrate at a temperature of 20°C., measured in the unit of Ωcm, and
[C] is a carbon concentration in the gallium nitride crystal substrate, measured in the unit of cm⁻³.

4. The gallium nitride crystal substrate according to claim 2, wherein the carbon concentration in the gallium nitride crystal substrate is 2×10¹⁷ cm⁻³ or more and 2.5×10¹⁸ cm⁻³ or less.

5. The gallium nitride crystal substrate according to claim 1, wherein a silicon concentration in the gallium nitride crystal substrate is 4×10¹⁷ cm⁻³ or less.

6. The gallium nitride crystal substrate according to claim 2, wherein a silicon concentration in the gallium nitride crystal substrate is 4×10¹⁷ cm⁻³ or less.

7. The gallium nitride crystal substrate according to claim 1, wherein an oxygen concentration in the gallium nitride crystal substrate is lower than a silicon concentration.

8. The gallium nitride crystal substrate according to claim 2, wherein an oxygen concentration in the gallium nitride crystal substrate is lower than a silicon concentration.

9. The gallium nitride crystal substrate according to claim 1, wherein a hydrogen concentration in the gallium nitride crystal substrate is 1×10¹⁸ cm⁻³ or less.

10. The gallium nitride crystal substrate according to claim 2, wherein a hydrogen concentration in the gallium nitride crystal substrate is 1×10¹⁸ cm⁻³ or less.

11. The gallium nitride crystal substrate according to claim 1, wherein a ratio of a hydrogen concentration to a carbon concentration in the gallium nitride crystal substrate is 0.7 or less.

12. The gallium nitride crystal substrate according to claim 2, wherein a ratio of a hydrogen concentration to a carbon concentration in the gallium nitride crystal substrate is 0.7 or less.

13. The gallium nitride crystal substrate according to claim 1, wherein an iron concentration and a manganese concentration in the gallium nitride crystal substrate are each 1×10¹⁷ cm⁻³ or less.

14. The gallium nitride crystal substrate according to claim 2, wherein an iron concentration and a manganese concentration in the gallium nitride crystal substrate are each 1×10¹⁷ cm⁻³ or less.

15. The gallium nitride crystal substrate according to claim 1, wherein a ratio of a resistivity of the gallium nitride crystal substrate at a temperature of 327°C. to a resistivity of the gallium nitride crystal substrate at a temperature of 20°C. is 1×10⁻⁷ or more and 3×10⁻⁷ or less.

16. The gallium nitride crystal substrate according to claim 1, wherein an activation energy of carbon in the gallium nitride crystal substrate is 0.95 eV or more and 1.10 eV or less, which is determined based on a slope of an Arrhenius plot of resistivity of the gallium nitride crystal substrate in a range where a reciprocal of temperature is 0.0025 K⁻¹ or less.

17. The gallium nitride crystal substrate according to claim 1, wherein the gallium nitride crystal substrate does not include, at least in the main surface, any region that has been grown with a facet other than (0001) as a growth plane.

18. A method for manufacturing a gallium nitride crystal substrate, the method comprising:
flowing hydrocarbon gas from a dopant gas line in a heated flow channel containing quartz, thereby forming a carbon coating on at least a part of an inner surface of a high temperature region of the flow channel, including at least a part of the dopant gas line; and
epitaxially growing a crystal layer including carbon-containing gallium nitride crystal above a seed substrate by supplying gallium chloride gas, nitrogen source gas, and hydrocarbon gas to the seed substrate, which is heated, through the flow channel having the carbon coating formed on the inner surface thereof, by an HVPE method.

19. The method for manufacturing a gallium nitride crystal substrate according to claim 18, wherein in the epitaxially growing the crystal layer, the hydrocarbon gas is supplied to the seed substrate from the dopant gas line in the flow channel together with a diluent gas containing 80% or more of nitrogen gas.

20. The method for manufacturing a gallium nitride crystal substrate according to claim 18, wherein in the epitaxially growing the crystal layer, the crystal layer is grown with (0001) as a growth plane without generating any facet other than (0001) over an entire main surface of the seed substrate.
